(19) United States
(12) Patent Application Publication
(10) Pub. No.: US 2017/0040567 A1
(43) Pub. Date: Feb. 9, 2017

(54) METHOD FOR COATING PACKAGING MATERIAL, DISPLAY PANEL, ITS MANUFACTURING METHOD, AND DISPLAY DEVICE

(71) Applicants: BOE TECHNOLOGY GROUP CO., LTD., Beijing (CN); ORDOS YUANSHENG OPTOELECTRONICS CO., LTD., Ordos (CN)

(72) Inventors: Zhiliang JIANG, Beijing (CN); Bo ZHANG, Beijing (CN); Fengli JI, Beijing (CN)

(73) Assignees: BOE TECHNOLOGY GROUP CO., LTD., Beijing (CN); ORDOS YUANSHENG OPTOELECTRONICS CO., LTD., Ordos (CN)

(21) Appl. No.: 15/134,670

(22) Filed: Apr. 21, 2016

(30) Foreign Application Priority Data
Aug. 3, 2015 (CN) 201510482026.9

(51) Int. Cl. H01L 51/52; C23C 14/06; C23C 14/04; H01L 51/56; C23C 14/35

(52) U.S. Cl. CPC H01L 51/5237; H01L 51/56; C23C 14/35; C23C 14/042; C23C 14/06

(57) ABSTRACT

The present disclosure provides a method for coating a packaging material, an OLED display panel and its manufacturing method, and a display device. The method for coating the packaging material includes steps of providing a base substrate in a chamber of a magnetron sputtering device, and depositing the packaging material at a region of the base substrate where the packaging material is to be coated by the magnetron sputtering device.

### CROSS-REFERENCE TO RELATED APPLICATION

The present application claims a priority of the Chinese Patent Application No. 201510482026.9 filed on Aug. 3, 2015, which is incorporated herein by reference in its entirety.

### TECHNICAL FIELD

The present disclosure relates to the field of display technology, in particular to a method for coating a packaging material, an organic light-emitting diode (OLED) display panel, a method for manufacturing the OLED display panel, and a display device.

### BACKGROUND

Among various display devices, an OLED display device has gradually become a mainstream product due to its advantages such as self-luminescence, rapid response speed, high brightness, low power consumption, simple manufacture process, low production cost, high light efficiency, and being easily flexible.

Usually, a conventional OLED display device includes a base substrate, an organic light-emitting structure arranged on the base substrate, and a glass cover plate. The glass cover plate and the base substrate are packaged by packing materials such as epoxy resin or glass cement. A resistance of the epoxy resin to water and oxygen is far less than that of the glass cover plate, while a resistance of the glass cement to water and oxygen is approximate to that of the glass cover plate. Hence, the OLED display device is usually packaged by the glass cement.

Usually, the glass cement is coated by screen printing, resulting in a sawtooth-like edge. Along with the elapse of time, microcracks may easily occur for the glass cement due to the sawtooth-like edge. In addition, a surface of the coated glass cement may have a bad appearance, i.e., the glass cement may have different thicknesses at different regions. During the subsequent packaging process using a laser beam, bubbles may easily occur in the surface of the glass cement, and a packaging effect thereof may be adversely affected. Further, it is difficult to accurately control a size of the coated glass cement, and usually an actual width of the glass cement is greater than a predetermined width, so it is adverse to provide the OLED display device with a narrow bezel.

### SUMMARY

An object of the present disclosure is to provide a method for coating a packaging material, an OLED display panel, its manufacturing method, and a display device, so as to overcome the above-mentioned drawbacks.

In one aspect, the present disclosure provides in some embodiments a method for coating a packaging material, including steps of providing a base substrate in a chamber of a magnetron sputtering device, and depositing the packaging material at a region of the base substrate where the packaging material is to be coated by the magnetron sputtering device.

Alternatively, the step of depositing the packaging material at the region of the base substrate where the packaging material is to be coated includes depositing the packaging material at the region of the base substrate where the packaging material is to be coated using a target made of a glass material.

Alternatively, the step of depositing the packaging material at the region of the base substrate where the packaging material is to be coated by the magnetron sputtering device includes: providing a mask plate between the target in the chamber and the base substrate in such a manner that the mask plate and the base substrate are arranged parallel to each other and spaced apart from each other at a predetermined interval, a hollowed-out region of the mask plate being located at a position corresponding to the region where the packaging material is to be coated; vacuumizing the chamber and supplying an inert gas into the chamber; and depositing the packaging material for a predetermined time period at a predetermined power and a predetermined pressure.

Alternatively, the predetermined interval is greater than 0 μm and less than 50 μm.

Alternatively, the inert gas is argon.

Alternatively, the predetermined power is 300 W to 700 W, the predetermined pressure is 10⁻³ to 10⁻⁵ Pa, and the predetermined time period is 0 min to 30 min.

Alternatively, the glass material is doped with a transition metal oxide.

Alternatively, the glass material is doped with a filler capable of reducing a linear thermal expansion coefficient of the glass material.

In another aspect, the present disclosure provides in some embodiments a method for manufacturing an OLED display panel, including steps of: depositing a packaging material on a cover plate using the above-mentioned method; forming on an array substrate a pattern including an organic light-emitting structure; and attaching and packaging the cover plate on which the packaging material is deposited and the array substrate with the organic light-emitting structure by a laser beam.

In yet another aspect, the present disclosure provides in some embodiments an OLED display panel manufactured by the above-mentioned method.

In still yet another aspect, the present disclosure provides in some embodiments a display device including the above-mentioned OLED display panel.

According to the method for coating the packaging material, the OLED display panel, its manufacturing method and the display device in the embodiments of the present disclosure, the base substrate is provided in the chamber of the magnetron sputtering device, and the packaging material is deposited at the region of the base substrate where the packaging material is to be coated by the magnetron sputtering device, so as to provide the deposited packaging material with a smooth edge and prevent the occurrence of sawteeth, thereby to prevent the packaging effect from being adversely affected due to the occurrence of microcracks at the edge of the packaging material along with the elapse of time. In addition, the packaging material is deposited at the region at an identical rate and within the predetermined time period, so as to provide the deposited packaging material with an identical thickness, thereby to prevent the occurrence of bubbles at the surface of the packaging material during the subsequent packaging process with the laser beam, and ensure the packaging effect. Moreover, it is able to accurately control a size of the deposited packaging material, thereby to enable an actual width of the packaging material to be substantially identical to a predetermined width.

### BRIEF DESCRIPTION OF THE DRAWINGS

FIGS. 1 and 2 are flow charts of a method for coating a packaging material according to one embodiment of the present disclosure; and

FIG. 3 is a schematic view showing a position relationship among a base substrate, a mask plate and a target according to one embodiment of the present disclosure.

### DETAILED DESCRIPTION OF THE EMBODIMENTS

The present disclosure will be described hereinafter in conjunction with the drawings and embodiments. The following embodiments are for illustrative purposes only, but shall not be used to limit the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

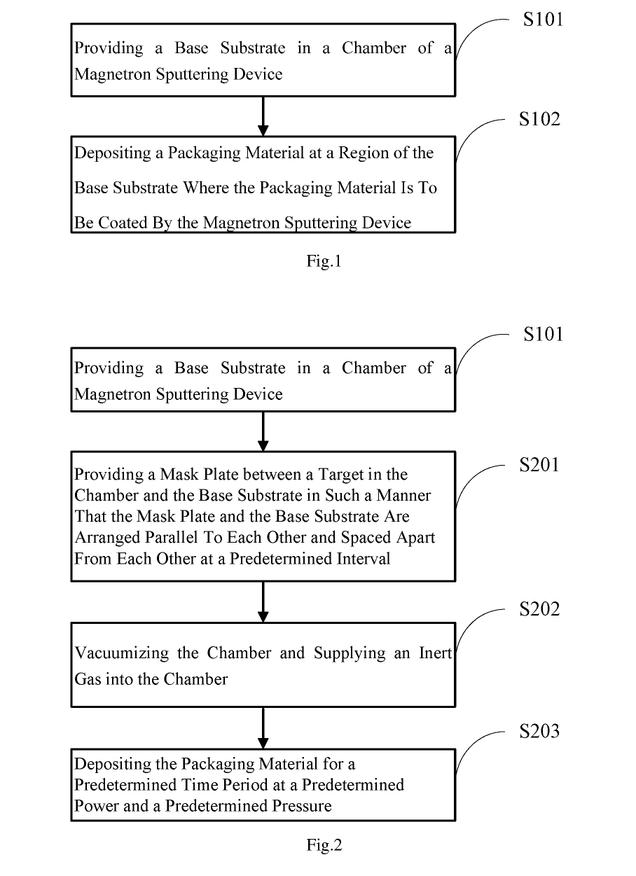

The present disclosure provides in some embodiments a method for coating a packaging material which, as shown in FIG. 1, includes Step S101 of providing a base substrate in a chamber of a magnetron sputtering device, and Step S102 of depositing the packaging material at a region of the base substrate where the packaging material is to be coated by the magnetron sputtering device.

According to the method for coating the packaging material in the embodiments of the present disclosure, the packaging material is deposited at the region of the base substrate where the packaging material is to be coated by the magnetron sputtering device, so as to provide the deposited packaging material with a smooth edge and prevent the occurrence of sawteeth, thereby to prevent the packaging effect from being adversely affected due to the occurrence of microcracks at the edge of the packaging material along with the elapse of time. In addition, the packaging material is deposited at the region at an identical rate and within the predetermined time period, so as to provide the deposited packaging material with an identical thickness, thereby to prevent the occurrence of bubbles at the surface of the packaging material during the subsequent packaging process with a laser beam, and ensure the packaging effect. Moreover, it is able to accurately control a size of the deposited packaging material, thereby to enable an actual width of the packaging material to be substantially identical to a predetermined width.

Alternatively, the step S102 of depositing the packaging material at the region of the base substrate where the packaging material is to be coated may include depositing the packaging material at the region of the base substrate where the packaging material is to be coated using a target made of a glass material.

To be specific, the target for the magnetron sputtering device is made of the glass material, and the glass material is deposited onto the region of the base substrate where the packaging material is to be coated by magnetron sputtering. The deposited glass material exhibits an excellent resistance to water and the oxygen, so as to seal an OLED display panel in a better manner, thereby to prevent an organic light-emitting structure in the OLED display panel from being damaged.

During the implementation, as shown in FIG. 2, the step S102 of depositing the packaging material at the region of the base substrate where the packaging material is to be coated by the magnetron sputtering device may include Steps S201 to S203.

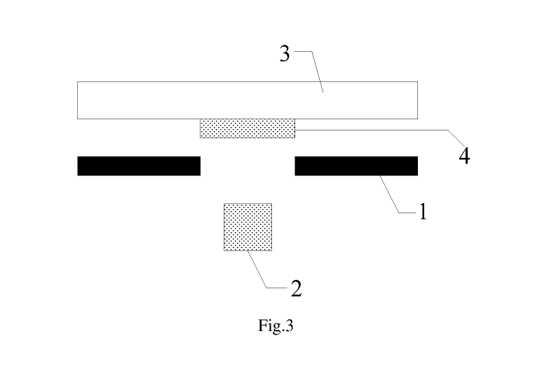

Step S201: providing a mask plate between the target in the chamber and the base substrate in such a manner that the mask plate and the base substrate are arranged parallel to each other and spaced apart from each other at a predetermined interval. A hollowed-out region of the mask plate is located at a position corresponding to the region where the packaging material is to be coated. To be specific, as shown in FIG. 3, the mask plate 1 is arranged between the target 2 and the base substrate 3. The mask plate 1 and the base substrate 3 are arranged parallel to each other and spaced apart from each other at a predetermined interval. During the deposition, the target 2 is sputtered onto the region of the base substrate 3 where the packaging material is to be coated through the hollowed-out region of the mask plate 1, so as to form a pattern of the packaging material 4. Of course, a position relationship between the target and the base substrate may not be limited to that shown in FIG. 3.

Step S202: vacuumizing the chamber and supplying an inert gas into the chamber.

Step S203: depositing the packaging material for a predetermined time period at a predetermined power and a predetermined pressure.

When the predetermined interval between the mask plate and the base substrate is too large, it may be difficult to accurately control the size of the deposited packaging material, and thereby an actual width of the deposited packaging material may be greater than the predetermined width, i.e., a width of the hollowed-out region of the mask plate. Hence, alternatively, the predetermined interval between the mask plate and the substrate may be greater than 0 μm and less than 50 μm.

During the implementation, after the chamber is vacuumized, argon (Ar) may be supplied into the chamber. Of course, any other inert gas that does not react with the packaging material may also be supplied into the chamber.

Alternatively, in order to provide the deposited packaging material with an appropriate thickness, the predetermined power may be 300 W to 700 W, the predetermined pressure may 10⁻³ to 10⁻⁵ Pa, and the predetermined time period may be 0 min to 30 min. During the implementation, the predetermined power, the predetermined pressure and the predetermined time period may be appropriately adjusted in accordance with the desired thickness of the packaging material.

Based on an identical inventive concept, the present disclosure further provides in some embodiments a method for manufacturing an OLED display panel, which includes steps of: depositing the packaging material on a cover plate using the above-mentioned method; forming on an array substrate a pattern including an organic light-emitting structure; and attaching and packaging the cover plate on which the packaging material is deposited and the array substrate with the organic light-emitting structure by a laser beam. Usually, the organic light-emitting structure includes an anode, a light-emitting layer and a cathode.

During the implementation, the packaging material may be deposited at the region of the cover plate where the packaging material is to be coated as follows.

At first, the cover plate is provided in the chamber of the magnetron sputtering device. Alternatively, the target for the magnetron sputtering device may be made of a glass material. The glass material exhibits an excellent resistance to water and oxygen, so as to seal the OLED display panel in a better manner, thereby to prevent the organic light-emitting structure in the OLED display panel from being damaged.

Next, the mask plate is provided between the target in the chamber and the cover plate in such a manner that the mask plate and the cover plate are arranged parallel to each other and spaced apart from each other at a predetermined interval. A hollowed-out region of the mask plate is located at a position corresponding to the region where the packaging material is to be coated. Alternatively, the predetermined interval between the mask plate and the cover plate may be greater than 0 μm and less than 50 μm.

Next, the chamber is vacuumized and then an inert gas is supplied into the chamber. To be specific, the inert gas may be Ar, or any other inert gas that does to react with the packaging material.

Finally, the packaging material is deposited for a predetermined time period at a predetermined power and a predetermined pressure. Alternatively, the predetermined power may be 300 W to 700 W, the predetermined pressure may be 10⁻³ to 10⁻⁵ Pa, and the predetermined time period may be 0 min to 30 min.

During the implementation, the cover plate on which the packaging material is deposited and the array substrate with the organic light-emitting structure may be attached and packaged by the laser beam as follows.

At first, the cover plate on which the packaging material is deposited is attached to the array substrate with the organic light-emitting structure.

Next, the packaging material between the cover plate and the array substrate is heated by the laser beam. Alternatively, a laser beam at an appropriate wavelength may be selected, so that the laser beam is merely absorbed by the packaging material rather than by the cover plate and the array substrate. In this way, a small amount of heat is transferred by the packaging material to the cover plate and the array substrate, so the thermal expansion of the cover plate and the array substrate may be omitted. In addition, when preparing the target, the glass material may be doped with a transition metal oxide and a filler. The transition metal oxide may absorb the laser beam and convert optical energy into heat so as to melt the glass cement, thereby to package the cover plate and the array substrate in a better manner. The filler may be used to reduce a linear thermal expansion coefficient of the glass material.

The implementation of the method for manufacturing the OLED display panel may refer to the implementation of the method for coating the packaging material, and thus will not be repeated herein.

Based on an identical inventive concept, the present disclosure further provides in some embodiments an OLED display panel manufactured by the above-mentioned method. The implementation of the OLED display panel may refer to the implementation of the method for manufacturing the OLED display panel, and thus will not be repeated herein.

Based on an identical inventive concept, the present disclosure further provides in some embodiments a display device including the above-mentioned OLED display panel. The display device may be any product or member having a display function, such as a mobile phone, a flat-panel computer, a television, a display, a laptop computer, a digital photo frame or a navigator. The implementation of the display device may refer to the implementation of the OLED display panel, and thus will not be repeated herein.

According to the method for coating the packaging material, the OLED display panel, its manufacturing method and the display device in the embodiments of the present disclosure, the base substrate is provided in the chamber of the magnetron sputtering device, and the packaging material is deposited at the region of the base substrate where the packaging material is to be coated by the magnetron sputtering device. In this way, it is able to provide the deposited packaging material with a smooth edge and prevent the occurrence of sawteeth, thereby to prevent the packaging effect from being adversely affected due to the occurrence of microcracks at the edge of the packaging material along with the elapse of time. In addition, the packaging material is deposited at the region at an identical rate and within the predetermined time period, so it is able to provide the deposited packaging material with an identical thickness. In this way, it is able to prevent the occurrence of bubbles at the surface of the packaging material during the subsequent packaging process with the laser beam, thereby to ensure the packaging effect. Moreover, it is able to accurately control the size of the deposited packaging material, thereby to enable the actual width of the packaging material to be substantially identical to the predetermined width.

The above are merely the preferred embodiments of the present disclosure. It should be appreciated that, a person skilled in the art may make further modifications and improvements without departing from the spirit of the present disclosure, and these modifications and improvements shall also fall within the scope of the present disclosure.

What is claimed is:

1. A method for coating a packaging material, comprising steps of:
providing a base substrate in a chamber of a magnetron sputtering device; and
depositing the packaging material at a region of the base substrate where the packaging material is to be coated by the magnetron sputtering device.

2. The method according to claim 1, wherein the step of depositing the packaging material at the region of the base substrate where the packaging material is to be coated comprises:
depositing the packaging material at the region of the base substrate where the packaging material is to be coated using a target made of a glass material.

3. The method according to claim 1, wherein the step of depositing the packaging material at the region of the base substrate where the packaging material is to be coated by the magnetron sputtering device comprises:
providing a mask plate between a target in the chamber and the base substrate in such a manner that the mask plate and the base substrate are arranged parallel to each other and spaced apart from each other at a predetermined interval, a hollowed-out region of the mask plate being located at a position corresponding to the region where the packaging material is to be coated;
vacuumizing the chamber and supplying an inert gas into the chamber; and
depositing the packaging material for a predetermined time period at a predetermined power and a predetermined pressure.

4. The method according to claim 3, wherein the predetermined interval is greater than 0 μm and less than 50 μm.

5. The method according to claim 3, wherein the inert gas is argon.

6. The method according to claim 3, wherein the predetermined power is 300 W to 700 W, the predetermined pressure is 10⁻³ to 10⁻⁵ Pa, and the predetermined time period is 0 min to 30 min.

7. The method according to claim 2, wherein the glass material is doped with a transition metal oxide.

8. The method according to claim 2, wherein the glass material is doped with a filler capable of reducing a linear thermal expansion coefficient of the glass material.

9. The method according to claim 2, wherein the step of depositing the packaging material at the region of the base substrate where the packaging material is to be coated by the magnetron sputtering device comprises:
providing a mask plate between the target in the chamber and the base substrate in such a manner that the mask plate and the base substrate are arranged parallel to each other and spaced apart from each other at a predetermined interval, a hollowed-out region of the mask plate being located at a position corresponding to the region where the packaging material is to be coated;
vacuumizing the chamber and supplying an inert gas into the chamber; and
depositing the packaging material for a predetermined time period at a predetermined power and a predetermined pressure.

10. The method according to claim 9, wherein the predetermined interval is greater than 0 μm and less than 50 μm.

11. The method according to claim 9, wherein the inert gas is argon.

12. The method according to claim 9, wherein the predetermined power is 300 W to 700 W, the predetermined pressure is 10⁻³ to 10⁻⁵ Pa, and the predetermined time period is 0 min to 30 min.

13. A method for manufacturing an organic light-emitting diode (OLED) display panel, comprising steps of:
depositing a packaging material on a cover plate using the method according to claim 1;
forming on an array substrate a pattern including an organic light-emitting structure; and
attaching and packaging the cover plate on which the packaging material is deposited and the array substrate with the organic light-emitting structure by a laser beam.

14. An organic light-emitting diode (OLED) display panel manufactured by the method according to claim 13.

15. A display device, comprising the OLED display panel according to claim 14.
